(19) United States
(12) Patent Application Publication
(10) Pub. No.: US 2016/0365478 A1
(43) Pub. Date: Dec. 15, 2016

(54) NANOSTRUCTURE MATERIAL STACK-TRANSFER METHODS AND DEVICES

(71) Applicants: The Board of Trustee of the University of Illinois, Urbana, IL (US); Rohm and Haas Electronic Materials LLC, Marlborough, MA (US); Dow Global Technologies LLC, Midland, MI (US)

(72) Inventors: Moonsub Shim, Savoy, IL (US); Nuri Oh, Champaign, IL (US); You Zhai, Urbana, IL (US); Sooji Nam, Urbana, IL (US); John A. Rogers, Urbana, IL (US); Bong Hoon Kim, Urbana, IL (US); Sang Y. Yang, Urbana, IL (US); Peter Trefonas, III, Medway, MA (US); Kishori Deshpande, Lake Jackson, TX (US); Jaebum Joo, Somerville, MA (US); Jieqian J. Zhang, Southborough, MA (US); Jong Keun Park, Westborough, MA (US)

(21) Appl. No.: 14/577,425

(22) Filed: Dec. 19, 2014

Related U.S. Application Data
(60) Provisional application No. 61/921,362, filed on Dec. 27, 2013.

(51) Int. Cl. H01L 33/00; H01L 33/08; H01L 33/06

(52) U.S. Cl. CPC H01L 33/0083; H01L 33/06; H01L 33/08

(57) ABSTRACT

In one aspect, methods are provided for fabrication of multiple layers of a nanostructure material composite, and devices produced by such methods. In another aspect, methods are provided that include use of an overcoating fluoro-containing layer that can facilitate transfer of a nanostructure material layer, and devices produced by such methods.

### FIELD

In one aspect, methods are provided for fabrication of multiple layers of a nanostructure material composite, and devices produced by such methods. In another aspect, methods are provided that include use of an overcoating fluoro-containing layer that can facilitate transfer of a nanostructure material layer, and devices produced by such methods.

### BACKGROUND

Nanostructure materials including quantum dot (QD) systems have been used in numerous application including light emitting devices, solar cells, optoelectronic devices, transistors, display devices and others. Nanostructure materials including quantum dots are semiconductor materials having a nanocrystal structure and sufficiently small to display quantum mechanical properties. See U.S. Published Application 2013/0056705 and U.S. Pat. No. 8,039,847.

Certain methods have been reported for making quantum dot devices. For various applications, including to produce more complex devices that include quantum dots, the need exists for improved fabrication processes.

### SUMMARY

We now provide improved methods for producing nanostructure material systems and devices produced by such methods. As discussed herein, the term nanostructure material includes quantum dot materials as well as nanocrystalline nanoparticles (nanoparticles) that comprise one or more heterojunctions such as heterojunction nanorods.

More particularly, in a first aspect, methods are provided for producing a nanostructure material composite or stack that comprises:

(a) providing on a first substrate a multiple-layer composite comprising 1) a nanostructure material layer and 2) one or more additional functional layers distinct from the nanostructure material layer;

(b) transferring the multiple-layer composite on to the second substrate.

The multiple-layer composite can be transferred by a variety of processes, with stamp-transfer often preferred. In one embodiment, a stamp contacts the top surface of the multiple-layer composite, removes the multiple-layer composite from the first substrate and deposits the multiple-layer composite on the second substrate. Thereafter, the stamp may be withdrawn from the composite.

The multiple-layer composite suitably comprises a nanostructure material layer (e.g. a quantum dot layer or a heterojunction nanomaterial layer) together with one or more functional layers such as an electron transport layer, hole transport layer, one or more sacrificial layers, electrode (e.g. cathode layer), and others.

In a further aspect, methods are provided for producing a nanostructure material composite or stack that comprises:

(a) providing on a first substrate a layered composite comprising a nanostructure material with an overcoating fluoro-containing layer;

(b) contacting the layered composite with a stamp;

(c) transferring the layered composite to a second substrate.

In preferred methods, the stamp contacts the overcoating or top fluoro-containing layer. The fluoro-containing layer can facilitate release of the nanostructure material layer composite to the receiver (second substrate). The fluoro-containing layer may comprise a variety of fluoro-containing materials such as fluoro-containing lower molecular weight non-polymeric compounds, fluorinated oligomer and fluorinated polymers, with fluorinated polymers often preferred. After transfer of the composition to the second substrate, the fluoro-containing layer may be suitably removed, e.g., by solvent washing.

Methods are also provided that utilize both of the above aspects of the invention. Thus, methods are provided for producing a nanostructure material composite that comprise:

(a) providing on a first substrate a multiple-layer composite comprising 1) a nanostructure material layer, 2) one or more additional functional layers distinct from the nanostructure material layer, and 3) an overcoating fluoro-containing layer;

(b) transferring the multiple-layer composite to a second substrate.

In these methods, the fluoro-containing layer may be as described above with fluorinated polymers often preferred. After transfer of the composition to the second substrate, the fluoro-containing layer may be suitably removed e.g. by solvent washing.

In the above methods, transferring of the composite is suitably completed in a single step, i.e., the entire multiple-layer composite is transferred as a single or integral unit from the first substrate (donor substrate) to the second substrate (receiver substrate).

In preferred methods, a plurality of composites may be transferred to a second substrate. For instance, a first composite that comprises a red emitting nanostructure material layer and a second composite that comprises a green emitting nanostructure material layer may be transferred from the first (donor) substrate to the second (receiver) substrate.

The invention also provides devices obtained or obtainable by the methods disclosed herein, including a variety of light-emitting devices, photodetectors, chemical sensors, photovoltaic device (e.g. a solar cell), transistors and diodes, as well as biologically active surfaces that comprise the systems disclosed herein.

Other aspects of the invention are disclosed infra.

### BRIEF DESCRIPTION OF THE DRAWINGS

FIG. 1 (which includes FIGS. 1A through 1E) shows schematically a preferred process of the invention.

FIG. 2 shows schematically a further preferred process of the invention.

FIG. 3 includes FIG. 3A labelled as “a”, FIG. 3B labelled as “b” and FIG. 3C labelled as “c”. FIG. 3A shows a transfer stamp with structured surface. FIG. 3B shows a donor substrate after retrieval. FIG. 3C shows quantum dot (QD) patterns on coated glass.

### DETAILED DESCRIPTION

We have now demonstrated transfer printing of multi-layered nanostructure material stacks in a single step.

Among other things, we have demonstrated transfer printing of nanostructure material stacks having 2 or more layers, including nanostructure material layer stacks having 2, 3 or 4 layers, e.g. effective transfers of stacks comprising a nanostructure material layer and an electron transport layer (2-layer stack); transfers of stacks comprising a nanostructure material layer, an electron transport layer and electrode layer (3-layer stack); and transfers of stacks comprising a hole transport layer, a nanostructure material layer, an electron transport layer and electrode layer (4-layer stack).

We have found the present transfer printing methods can provide a number of performance benefits.

In particular, we have found that ordering of a nanostructure material layer can be increased relative to a comparable the nanostructure material layer in a comparable spin cast-produced device. Without being bound by theory, it is believed such increased ordering of a nanostructure material layer can result at least in part due to applied pressure associated with the present printing process.

Additionally, by the present stack transfer printing methods materials in each stack layer and the thickness of each layer each can be readily optimized. Further, the energy band diagram of a produced nanostructure material LED device can be optimized. Thus, transfer printing has been demonstrated for a multiple layer stack that comprises a nanostructure material layer, electron transport layer and cathode layer onto a hole transport layer coated substrate, where each layer can be individually optimized to maximize performance of a produced RGB nanostructure material-LED. Thus, in one preferred specific system, a stack of red or green quantum dot/ZnO or TiO₂/aluminum can be transferred onto a poly[9,9-dioctylfuorenyl-2, 7-diyl]-co-(4,4′-sec-butylphenyl)diphenylamine)](TFB) coated PEDOT:PSS/indium tin oxide substrate.

As referred to herein, layers (e.g. a first layer and a second layer) of a nanostructure material composite will be distinct when at least 20, 30, 40, 50, 60, 70 or 80 weight percent of a first layer is composed of one or more materials that are not present in a second layer.

Cross-sectional dimensions of layers of a nanostructure material composite can vary widely and suitably may be e.g. 1000 μm or less by 1000 μm or less, and typically smaller such as 500 μm or less by 500 μm or less, or 200 μm or less by 200 μm or less, or even 150 μm or less by 150 μm or less, or even 100 μm or less by 100 μm or less.

Thicknesses of layers of a nanostructure material composite also can vary widely and for example suitably may be 5 nm to 100 nm in thickness, more typically 10 nm to 20 nm or 50 nm in thickness.

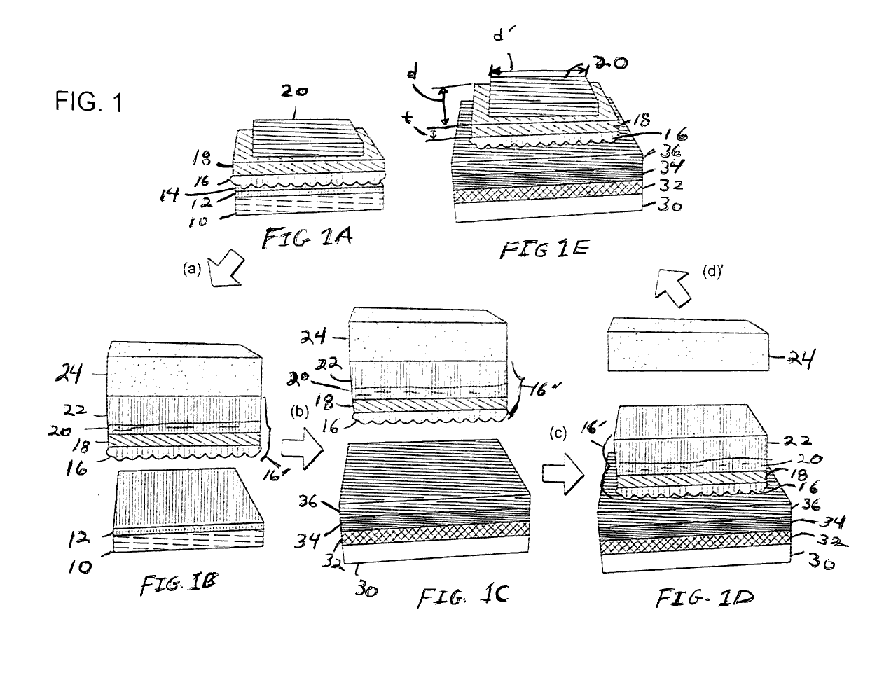

Referring now to the drawings, FIG. 1 depicts schematically a preferred method of the invention.

As shown in FIG. 1A, donor substrate 10 which may be a silicon wafer optionally coated such as with a silane material e.g. octadecyltrichlorosilane preferably to provide self-assembled monolayer (SAM) layer 12. The silane material may be suitably applied e.g. by dip coating. Excess silane material may be removed such as by ultrasonication following by thermal treatment to form a silane networked layer 12 over wafer 10. Thermal treatment may be e.g. 100° C. or greater for 15 to 60 minutes, depending on the silane reagent utilized. Other materials suitable for forming layer 12 include e.g. other silane materials such as octyltrichlorosilane and trichloro(1H,1H,2H,2H-perfluorooctyl)silane as well as fluorinated materials.

If desired, a sacrificial layer 14 may be formed above SAM layer 12. Layer 14 suitably may comprise one or more polymers that may be readily removed e.g. at temperature of from about 30° C. to 140° C. Exemplary materials for layer 14 may include e.g. polyethylene oxide, polyvinyl alcohol, polyamic acid, polyvinylpyrrolidone and polyvinylmethylether, used either alone or in combination in the sacrificial layer. Layer 14 can facilitate separation of the nanostructure material layer 16 from the donor substrate during the transfer process as illustrated in FIG. 1B.

Such a sacrificial layer 14 may be particularly preferred where the first layer of the composite that will be transferred is not the nanostructure material layer, but another layer such as a charge transport layer that comprises relatively polar components which may be difficult to effectively spin coat onto an ODTS treated substrate. In such a preferred embodiment, a sacrificial layer 14 may comprise one or more materials that have a higher surface energy than ODTS or other surface material of the underlying donor substrate but still a surface energy sufficiently distinct from the next applied composite layer (e.g. a charge transport layer) to ensure successful release of the composite from the donor substrate during subsequent processing.

Nanostructure material layer 16 may be applied as a solution over underlying layer(s) e.g. by spin coating, spray coating, dip coating and the like. The nanostructure material layer may be applied as monolayer where the applied nanostructure material is arranged in a two-dimensional array. It also may be preferred that the nanostructure material is applied to provide a three-dimensional array.

The applied nanostructure material layer may comprise a variety of materials that will be understood to be embraced by the term nanostructure material, nanostructure material layer of other similar term herein.

Thus, as discussed, above, the term nanostructure material as used herein includes both quantum dot materials as well as nanocrystalline nanoparticles (nanoparticles) that comprise one or more heterojunctions such as heterojunction nanorods.

An applied quantum dot suitably may be Group II-VI material, a Group III-V material, a Group V material, or a combination thereof. The quantum dot suitably may include e.g. at least one selected from CdS, CdSe, CdTe, ZnS, ZnSe, ZnTe, HgS, HgSe, HgTe, GaN, GaP, GaAs, InP and InAs. Under different conditions, the quantum dot may include a compound including two or more of the above materials. For instance, the compound may include two or more quantum dots existing in a simply mixed state, a mixed crystal in which two or more compound crystals are partially divided in the same crystal e.g. a crystal having a core-shell structure or a gradient structure, or a compound including two or more nanocrystals. For example, the quantum dot may have a core structure with through holes or an encased structure with a core and a shell encasing the core. In such embodiments, the core may include e.g. one or more materials of CdSe, CdS, ZnS, ZnSe, CdTe, CdSeTe, CdZnS, PbSe, AgInZnS, and ZnO. The shell may include e.g. one or more materials selected from CdSe, ZnSe, ZnS, ZnTe, CdTe, PbS, TiO, SrSe, and HgSe.

Passivated nanocrystalline nanoparticles (nanoparticles) that comprise a plurality of heterojunctions suitably facilitate charge carrier injection processes that enhance light emission when used as a device. Such nanoparticles also may be referred to as semiconducting nanoparticles and may comprise a one-dimensional nanoparticle that has disposed at each end a single endcap or a plurality of endcaps that contact the one-dimensional nanoparticle. The endcaps also may contact each other and serve to passivate the one-dimensional nanoparticles. The nanoparticles can be symmetrical or asymmetrical about at least one axis. The nanoparticles can be asymmetrical in composition, in geometric structure and electronic structure, or in both composition and structure. The term heterojunction implies structures that have one semiconductor material grown on the crystal lattice of another semiconductor material. The term one-dimensional nanoparticle includes objects where the mass of the nanoparticle varies with a characteristic dimension (e.g. length) of the nanoparticle to the first power. This is shown in the following formula (1): MαLd where M is the mass of the particle, L is the length of the particle and d is an exponent that determines the dimensionality of the particle. Thus, for instance, when d=1, the mass of the particle is directly proportional to the length of the particle and the particle is termed a one-dimensional nanoparticle. When d=2, the particle is a two-dimensional object such as a plate while d=3 defines a three-dimensional object such as a cylinder or sphere. The one-dimensional nanoparticles (particles where d=1) includes nanorods, nanotubes, nanowires, nanowhiskers, nanoribbons and the like. In one embodiment, the one-dimensional nanoparticle may be cured or wavy (as in serpentine), i.e. have values of d that lie between 1 and 1.5.

Exemplary preferred materials are disclosed in U.S. patent application Ser. Nos. 13/834,325 and 13/834,363, both incorporated herein by reference. See also Example 8 which follows for an exemplary preferred material.

The one-dimensional nanoparticles suitably have cross-sectional area or a characteristics thickness dimension (e.g., the diameter for a circular cross-sectional area or a diagonal for a square of square or rectangular cross-sectional area) of about 1 nm to 10000 nanometers (nm), preferably 2 nm to 50 nm, and more preferably 5 nm to 20 nm (such as about 6, 7, 8, 9, 10, 11, 12, 13, 14, 15, 16, 17, 18, 19 or 20 nm) in diameter. Nanorods are suitably rigid rods that have circular cross-sectional areas whose characteristic dimensions lie within the aforementioned ranges. Nanowires or nanowhiskers are curvaceous and have different or vermicular shapes. Nanoribbons have cross-sectional area that is bounded by four or five linear sides. Examples of such cross-sectional areas are square, rectangular, patallelopipeds, rhombohedrals, and the like. Nanotubes have a substantially concentric hole that traverses the entire length of the nanotube, thereby causing it to be tube-like. The aspect ratios of these one-dimensional nanoparticles are greater than or equal to 2, preferably greater than or equal to 5, and more preferably greater than or equal to 10.

The one-dimensional nanoparticles comprise semiconductors that suitably include those of the Group II-VI(ZnS, ZnSe, ZnTe, CdS, CdTe, HgS, HgSe, HgTe, and the like) and III-V (GaN, GaP, GaAs, GaSb, InN, InP, InAs, InSb, AlAs, AlP, AlSb, and the like) and IV (Ge, Si, Pb and the like) materials, an alloy thereof, or a mixture thereof.

Nanostructure materials including quantum dot materials are commercially available and also may be prepared for example by a standard chemical wet method using a metallic precursor as well as by injecting a metallic precursor into an organic solution and growing the metallic precursor. The size of the nanostructure material including quantum dot may be adjusted to absorb or emit light of red (R), green (G), and blue (B) wavelengths.

An electron transport layer 18 may be formed over nanostructure material layer 16. For example, layer 18 may comprise ZnO for a red nanostructure material layer and TiO₂ for a green nanostructure material layer. ZnO or TiO₂ suitably may be applied as a spin-coated sol-gel solution followed by thermal treatment of the applied layer 18, e.g. annealing under vacuum at 80° C. to 150° C. for 15 to 60 minutes. Electrode 20 then may be applied. For instance, a micro-patterned Al electrode may be produced using a mask and electron beam evaporator.

As shown in FIG. 1B, fluoro-containing layer 22 may be applied as a top layer and will facilitate mating and subsequent separation from transfer stamp 24. Layer 22 may comprise a variety of materials with fluorine substitution, with one or more fluorinated polymersbeing generally preferred. Suitable materials include Teflon AF (fluoropolymer sold by DuPont) and aromatic nitroester fluoropolymers.

Stamp 24 then contacts the nanostructure material composite stack of layers 16′, particularly electrode 20 or if present overcoating layer 22. As shown in FIG. 1B, stamp 24 is withdrawn and separates nanostructure material layer 16 from SAM layer 12 and donor substrate 10. As should be understood, references to a nanostructure material layer stack 16′ indicates the depicted nanostructure material layer 16 together with one or more additional layers such as one or more of layers 18, 20 and 22 deicted in FIGS. 1A through 1E.

A variety of stamping processes may be utilized. For instance, a single stamp may be used to transfer a single composite, or a plurality of stamps may be used in a single or coordinated process to transfer a plurality of composites. For instance a roller-type process may be employed where a roller comprises multiple stamp units, or a sheet transfer process may be utilized where a transfer sheet is used that comprises multiple stamp units.

Stamp 24 suitably may be formed for a variety of materials, e.g. an elastomeric polymer, an epoxy-based material, or a polysiloxane such as a polydimethylsiloxane (PDMS) material. Stamp 24 also may be preferably patterned to enhance adhesion to the nanostructure material layer composite. Patterning of the stamp may be accomplished e.g. by etching of a mold such as by microlithography and an elastomer stamp fabricated from the etched, patterned mold.

As shown in FIGS. 1B and 1C, the multiple-layer nanostructure material layer stack 16′ affixed to stamp 24 is removed from first substrate 10 for transferring to second substrate (receiver substrate) 30 that may comprise one or more functional layers such as depicted layers 32, 34 and 36. Prior to transfer of the nanostructure material layer stack, receiver substrate 30 may be heated e.g. at from 40° C. to 90° C. to facilitate the nanostructure material stack transfer printing process.

Preferably, pressure is applied when stamp 24 contacts the nanostructure material layer stack 16′. It has been found that applying pressure through stamp 24 during retrieval of the nanostructure material stack can enhance retrieval efficiency with negligible residue of nanostructure material film layer 16 being left on the donor substrate. It was also found that fractured edge of retrieved region in the nanostructure material film was clearer when pressure through stamp 24 was applied. Additionally, it has been found that a nanostructure material layer transferred from a stamp contacting the nanostructure material layer stack 16′ with applied pressure was denser than that with only conformal contact.

If employed, sacrificial layer 14 may be suitably removed after withdrawing nanostructure material layer stack 16′ from the donor substrate 10. Removal of layer 14 can be accomplished by a variety of methods including treatment with a solvent for the layer 14.

The nanostructure material layer stack 16′ affixed to stamp 24 then can be transferred to second substrate 30 which may comprise one or more additional layers such as layers 32, 34 and 36 as depicted in FIGS. 1C, 1D and 1E.

A variety of multi-layer nanostructure material composite or stacks can be transfer printed in accordance with the present methods. One preferred transferred printed composite will comprises distinct layers of hole injection layer/hole transport layer/electron blockage layer+nanostructure material+hole blockage layer/electron transport layer/electron injection layer+cathode.

Substrate 30 suitably may be a rigid (e.g. glass) or flexible (e.g. plastic) material. Layers 32, 34 and 36 may include one or more functioning layers. For example, layer 32 may be an anode, layer 34 may be a hole injection layer and layer 36 may be a hole transport layer.

As depicted in FIG. 1D, stamp 24 is separated from the nanostructure material layer stack. Separation of stamp 24 and the nanostructure material layer stack may be aided for example by exposure to ultrasonic waves.

The fluoro-containing layer 22 also then may be removed, for example by treatment with a solvent for the fluoro-containing material of layer 22.

As discussed above and with reference to FIG. 1E, cross-sectional dimensions and thicknesses of a layer of a nanostructure material composite suitably may vary rather widely. For instance, a layer thickness t as depicted in FIG. 1E suitably may be from 5 nm to 100 nm, more typically 10 nm to 50 nm. The cross-sectional dimensions d by d′ as depicted in FIG. 1E suitably may be for example may be 1000 μm or less by 1000 μm or less, or smaller as discussed above.

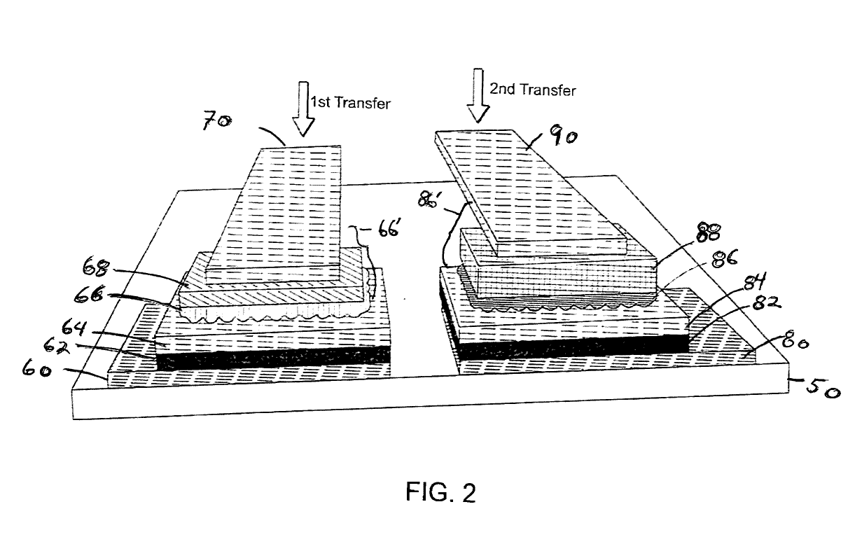

FIG. 2 shows the transfer printing of a plurality of nanostructure material layer stacks on a single substrate. Thus, receiver substrate 50 which may be indium tin oxide (ITO) coated glass may have coated thereon layers 60, 62, 64 which suitably may be an anode layer 60, hole injection layer 62 and hole transport layer 64. Multiple layer nanostructure material composite 66′ that includes nanostructure material layer 66, electron transport layer 68 and cathode 70 may be transfer printed onto the coated receiver substrate 50. In a second transfer, receiver substrate 50 may have coated thereon layers 80, 82 and 84 which suitably may be an anode layer 80, hole injection layer 82 and hole transport layer 84. Multiple layer nanostructure material composite 86′ that includes nanostructure material layer 86, electron transport layer 88 and cathode 90 may be transfer printed onto the coated receiver substrate 50.

The plurality of multiple layer nanostructure material composites (66′, 86′) that are transferred as depicted in FIG. 2 suitably are distinct. Thus, electron transport layer 68 may comprise zinc oxide (ZnO) and nanostructure material layer 66 may comprise an array of red-emitting quantum dots, while electron transport layer 88 may comprise titanium oxide (TiO₂) and nanostructure material layer 86 may comprise an array of green-emitting quantum dots.

A variety of devices may be fabricated utilizing methods of the invention, including displays and other optoelectronic devices including photodetectors.

For instance, a preferred optoelectronic device may include a substrate which may be rigid such as indium tin oxide coated glass or a flexible plastic that comprises a nanostructure material layer stack of the configuration and transferred to the substrate as discussed above and that comprises a nanostructure material layer, multiple electrodes (particularly an anode and a cathode) which are connected to a power source. A first charge transport layer can be positioned between a nanostructure material layer and a first electrode and a second charge transport layer can be positioned between the nanostructure material active layer and the second electrode. The device may comprise additional layers as disclosed herein, e.g. a hole injection layer.

More particularly, a first anode layer of the device may be formed on a glass or flexible substrate from indium tin oxide or other suitable oxide. A hole transport layer then formed over the anode layer. A variety of materials may be used to form a hole transport layer, such as poly(3,4-ethylenedioxythiophene) (PEDOT), poly(styrenesulfonate) (PSS) and mixtures thereof.

A nanostructure material layer then may be formed over the hole transport layer. Suitably the nanostructure material may have a size and configuration to emit or absorb a desired color, i.e. red, green or blue. For instance, suitable nanostructure materials may include those that have a diameter of 1 nm to 50 nm, more typically a diameter of 1 nm to 10 nm or 20 nm.

An electron transport layer (ETL) may be positioned between the nanostructure material layer and a cathode layer. Suitable materials to form the electron transport layer include metal oxides such as TiO₂, ZrO₂, HfO₂, MoO₃, CrO₃, V₂O₅, WO₃, NiO, Cr₂O₃, Co₃O₄, MoO₂, CuO, Ta₂O₅, Cu₂O, CoO as well as other inorganic materials such as Si₃N₄. TiO₂ may be preferred for many applications. The cathode may be suitably formed from a variety of materials such as Mg, K, Ti, Li, and the like as well as alloys thereof or layered structures of those materials.

For use of the device, voltage can be applied through the anode and cathode which will result in light being emitted from the nanostructure material layer.

The following examples are illustrative of the invention.

### EXAMPLE 1

### Part 1. Preparation of Donor and Receiver Substrates

To facilitate the retrieval of thin films of quantum dots from a donor substrate, adhesion between the substrate and quantum dot film should be minimized. To realize that goal, Si wafer substrates were used, treated with octadecyltrichlorosilane (ODTS) to form self-assembled monolayers (SAMs) with low adhesion to the quantum dots. The process involved Si (or SiO₂) chips cleaned in piranha solution for 30 min, and then dipped in ODTS solution in hexane (10 mM) for 60 min. The chips were removed from the ODTS solution and then ultrasonicated in chloroform for 3 min to remove excess ODTS. The resulting Si substrates modified with ODTS SAM were baked at 120° C. for 20 min to form siloxane networks over the entire substrate.

Commercially available quantum dot solutions (CdSe/ZnS, Aldrich, dispersed in toluene, emission wavelength 610 nm) were used to form a quantum dot thin film. Before spin coating, the quantum dot solution was cleaned to remove excess aliphatic amines that are typically added to improve the shelf life. For cleaning, 0.5 ml of anhydrous toluene was added to the quantum dot solution for dilution and then 4 ml of methanol for precipitation of quantum dot solid. By centrifuging and then subsequently removing the toluene/methanol, a quantum dot solid was obtained at the bottom of tube. Cleaned colloidal quantum dot solution was prepared by dispersing this solid in cyclohexane. Quantum dot thin films were formed by spin coating the cleaned colloidal quantum dot solution on the ODTS treated Si wafer. It was found that quantum dot thin films were retrieved efficiently with stamp when quantum dot film was formed from colloidal solution cleaned once with the cleaning procedure described above (cf. quantum dot film formed from solution that was cleaned twice was not retrieved.)

The receiver substrate was prepared by spin coating poly[(9,9-dioctylfluorenyl-2, 7-diyl)-co-(4,4′-(N-(4-sec-butylphenyl))diphenylamine)] (TFB) solution in xylene (1 wt %) on glass substrate and baking it at 180° C. for 30 min.

### Part 2. Preparation of PDMS Stamp

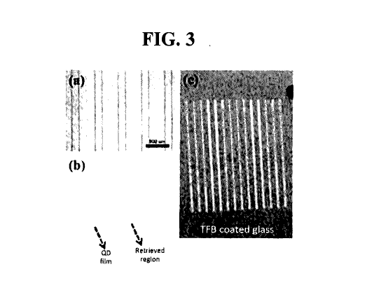

To prepare elastomeric stamps with representative structured surfaces for printing, a mold having a repeated pattern of 100 um relief and 200 um recess was fabricated with photopatternable epoxy (SU-8). A mixture of PDMS prepolymer and curing agent (10:1 by weight) was poured on the fabricated mold and cured at 70° C. for 1 hr. The resulting PDMS stamp (as shown in FIG. 3A) was peeled off from the mold after curing. Note that the fabricated mold was treated with (tridecafluoro-1,2,2-tetrahydrooctyl)-1-tricholorosilane in vacuum desiccator for 60 min before PDMS stamp preparation to facilitate removal from the mold.

### Part 3. Transfer Printing Using Automated Printer with Controlled Retraction Speeds

An automated printer was used to carry out transfer printing with precise control of retraction speed. For the retrieval of quantum dot film, PDMS stamp was retracted with high retraction speed of 80 mm/sec after making contact of stamp to surface of quantum dot film. Quantum dot films retrieved onto the stamp was printed on the receiver substrate with low retraction speed of 1 um/sec. FIGS. 3B and 3C show the retrieved region of quantum dot film on the donor substrate and the printed quantum dot pattern on TFB coated glass, respectively.

To check the effect of pressure applied during contact between stamp and donor substrate on the efficiency of retrieval of quantum dot film, the surface of donor substrate after retrieval was investigated with AFM in cases of conformal contact and of contact with applied pressure before retrieval. Applying pressure during retrieval resulted in more efficient retrieval with negligible quantum dot film residue left on the donor substrate. Also, the fractured edge of retrieved region in quantum dot film was clearer when pressure was applied. For the printed film, it was observed that the quantum dot film printed from the stamp inked with applied pressure was denser than that with only conformal contact, likely due to Poisson effect of elastomeric PDMS stamp.

### EXAMPLE 2

### Fabrication of a Quantum Dot LED

### Part 1. Development of Standard QD-LED Test Device

A quantum dot-LED test structure was developed with optimum materials combinations for each of the layers in the device. In this device design, both anode and cathode are patterned and the overlapped area between anode and cathode is a single pixel with emitting area of 10 mm². One device contains six pixels. In addition, solution processible materials were used for all the charge injection/transport layers: LED device included ITO (anode, ITO glass from Aldrich, surface resistivity 15˜25 ohm/sq), PEDOT:PSS (hole injection layer, Clevios P VP AI4083), TFB (hole transport layer), quantum dot (emissive layer, the same material as used in transfer printing test), ZnO nanoparticle (electron transport layer, 30 mg/ml in butanol, synthesized in Shim group) and Al (cathode). Device fabrication started from patterning of ITO, and successive spin coating of each layer was performed on the patterned ITO. Deposition of Al electrodes through a shadow mask by electron beam evaporation completed the device fabrication. Processing steps included: patterning of the ITO (photolithography and etching) following by UV/ozone treatment. PEDOT-PSS was spincoated in cleanroom environment following by baking at 180° C. for 10 minutes in a glove box. TFB (1 wt % in m-xylene) was then spincoated following by baking at 180° C. for 30 minutes in a glove box. The quantum dot composition (dispersed in cyclohexane) was then spincoated following by baking at 80° C. for 30 minutes in a glove box. ZnO (30 mg/ml in butanol) was then spincoated following by baking at 10° C. for 3 minutes in a glove box. An Al layer was then deposited through a shadow mask. The thus produced quantum dot-LED emitted light under applied voltage of 10V.

### Part 2. Fabrication of Quantum dot-LED via Transfer Printing of Quantum dot/ETL/Cathode Stack

Fabrication of QD/ETL/cathode stack began with ODTS treatment of Si chip and the formation of quantum dot film as described in Example 1, Part 1 above. On quantum dot film, ZnO nanoparticle (30 mg/ml in butanol) was spin coated and then Al was deposited through shadow mask to form Al patterns.

It was found that the fabricated stack could be easily retrieved with a flat PDMS stamp. However, retrieved stack was not printed on receiver substrate (TFB coated glass) because the crack for the delamination of Al from PDMS stamp was not initiated at that interface; instead, cracks always initiated and propagated at the interface between QD and TFB layers, resulting in the failure of printing.

A fluoropolymer layer was then included on the Al layer to provide reduced adhesion to the PDMS stamp. The fluoroether solvent used for preparation of fluoropolymer solution does not affect the physical or electrical properties of organic electronic materials. Therefore, it can be expected the application of fluoropolymer film on the stack leaves quantum dot and ZnO layers intact both physically and electrically.

As a result of the application of fluoropolymer layer (spin coated at 2000 rpm for 30 sec, baked at 95° C. for 60 sec), retrieved stack was successfully printed on the ITO/PEDOT:PSS/TFB receiver substrate. The receiver substrate was heated at 50° C. to facilitate the printing process. The produced QD-LED emitted light when voltage was applied (approximately 7 V).

### EXAMPLE 3

### Part 1. Preparation of Donor Substrates

Silicon wafer was immersed in piranha solution for 30 min, and then dipped in octadecyltrichlorosilane (ODTS) solution in hexane (10 mM) for 60 min. Afterward, it was ultrasonicated in chloroform for 3 min to remove the excess ODTS. The resulting Si substrates modified with ODTS SAM were baked at 120 ° C. for 20 min to form siloxane networks over the entire substrate. Commercially available QD solutions (CdSe/ZnS, Aldrich, dispersed in toluene) were used to form a quantum dot thin film. Before spin coating, the quantum dot solution was cleaned to remove excess aliphatic amines that are typically added to improve the shelf life. Then, ZnO (30 mg/ml in butanol) or TiO2 (TYZOR® 131 organic titanate) sol-gel solution was spin-coated on the quantum dot thin film and thermally annealed in vacuum (100° C., 30 min). A micro-patterned Al electrode was fabricated using a shadow mask and electron beam evaporator.

### Part 2. Preparation of Receiver Substrates

The ITO substrate (Aldrich, surface resistivity 15˜25 ohm/sq) was cleaned by acetone spin-washing. Then, PEDOT:PSS (hole injection layer, Clevios PVP AI4083) and poly[(9,9-dioctylfluorenyl-2, 7-diyl)- co-(4,4′-(N-(4-sec-butylphenyl))diphenylamine)] (TFB, solution in xylene (1 wt %)) were spin-coated on ITO substrate and baked at 180° C. for 30 min.

### Part 3. Stack Transfer Printing Process

The PDMS stamp was constructed by mixing PDMS prepolymer with the curing agent (10:1 by weight) which was then cured at 70° C. for 1 hr. The fluoropolymer layer (OSCoR 2312 Photoresist Solution) was spin-coated at 2000 rpm for 30 sec and baked at 95° C. for 60 sec. Afterward, the receiver substrate was heated at 50° C. to facilitate the stack transfer printing process.

### Part 4. Optical Characterization of Quantum dot-LED Device

In this device design, both anode and cathode are patterned. The overlapped area between anode and cathode is a single pixel with emitting area of 10 mm². Luminance-current-voltage characteristics can be measured using a system incorporating a PR-655 spectroradiometer and a Keitheley 2635 source meter. The relative electroluminescence of devices was measured using a Si photodiode.

### EXAMPLE 4

### Heterojunction Nanorods

### Part 1. Preparation of Donor Substrates

Silicon wafer was immersed in piranha solution for 30 min, and then dipped in octadecyltrichlorosilane (ODTS) solution in hexane (10 mM) for 60 min. Afterward, it was ultrasonicated in chloroform for 3 min to remove the excess ODTS. The resulting Si substrates modified with ODTS SAM were baked at 120° C. for 20 min to form siloxane networks over the entire substrate. Heterojunction nanorod solutions (CdS/CdSe/ZnSe double heterojunction nanorods (DHNRs) were used to form a nanorod thin film. Before spin coating, the nanorod solution was cleaned to remove excess aliphatic amines that are typically added to improve the shelf life. Then, ZnO (30 mg/ml in butanol) or TiO2 (TYZOR® 131 organic titanate) sol-gel solution was spin-coated on the nanoroad thin film and thermally annealed in vacuum (100° C., 30 min). A micro-patterned Al electrode was fabricated using a shadow mask and electron beam evaporator.

### Part 2. Preparation of Receiver Substrates

The ITO substrate (Aldrich, surface resistivity 15˜25 ohm/sq) was cleaned by acetone spin-washing. Then, PEDOT:PSS (hole injection layer, Clevios PVP AI4083) and poly[(9,9-dioctylfluorenyl-2, 7-diyl)- co-(4,4′-(N-(4-sec-butylphenyl))diphenylamine)] (TFB, solution in xylene (1 wt %)) were spin-coated on ITO substrate and baked at 180° C. for 30 min.

### Part 3. Stack Transfer Printing Process

The PDMS stamp was constructed by mixing PDMS prepolymer with the curing agent (10:1 by weight) which was then cured at 70° C. for 1 hr. The fluoropolymer layer (OSCoR 2312 Photoresist Solution) was spin-coated at 2000 rpm for 30 sec and baked at 95° C. for 60 sec. Afterward, the receiver substrate was heated at 50° C. to facilitate the stack transfer printing process.

### Part 4. Optical Characterization of Quantum dot-LED Device

In this device design, both anode and cathode are patterned. The overlapped area between anode and cathode is a single pixel with emitting area of 10 mm². Luminance-current-voltage characteristics can be measured using a system incorporating a PR-655 spectroradiometer and a Keitheley 2635 source meter. The relative electroluminescence of devices was measured using a Si photodiode.

### EXAMPLE 5

### Stack Transfer Printing for Flexible Quantum Dot LED Display

A flexible quantum dot LED display was produced using the stack transfer printing method disclosed herein. Thus, a receiver substrate of an ITO-coated polyethylene terephthalate (PET) film was prepared. A PEDOT:PSS layer was applied over the ITO-coated PET film capped with a TFB layer. A quantum dot layer composite that comprised in sequence red quantum dot layer, ZnO layer, Al electrode (100 nm) and fluoropolymer layer (1.4 um) as transferred onto the coated flexible receiver substrate using an etched PDMS stamp affixed to the top fluoropolymer layer of the quantum dot layer composite. The stamp was removed and the device processed as disclosed in above examples. The produced flexible quantum dot LED display emitted light when voltage was applied.

### EXAMPLE 6

### Transfer of Two Layer Quantum Dot Composite

A quantum dot composition (CdSe/ZnS, Aldrich, dispersed in toluene) is spin-coated (2000 rpm) onto an ODTS-coated silicon wafer substrate and thermally annealed (90° C., 20 minutes). Next, ZnO solution (sol-gel) is spin-coated (3000 rpm) and thermally annealed in vacuum (100° C., 30 min). Then, fluoropolymer solution is spin-coated (4000 rpm) on this stack (ODTS/QD/ZnO) and slightly baked (100° C., 3 min). The thus constructed composite can be transferred using a stamp as described in Part 3 of Examples 3 and 4 above.

### EXAMPLE 7

### Transfer of Four Layer Quantum Dot Composite

TFB is spin-coated on an ODTS-coated silicon wafer (3000rpm) and thermally annealed (180° C., 30 min). Next, a quantum dot composition (CdSe/ZnS, Aldrich, dispersed in toluene) is spin-coated (2000 rpm) onto the TFB layer and thermally annealed (90° C., 20 min). Then, ZnO solution (sol-gel) is spin-coated (3000 rpm) and thermally annealed in vacuum (100° C., 30 min). Thereafter, Al is deposited by e-beam evaporator. Then, fluoropolymer solution is spin-coated (4000 rpm) on this stack (ODTS/TFB/QD/ZnO/Metal) and slightly baked (100° C., 3 min). The thus constructed composite can be transferred using a stamp as described in Part 3 of Examples 3 and 4 above.

### EXAMPLE 8

This example demonstrates the manufacturing the passivated nanoparticles which can be used in a quantum dot layer as disclosed herein. The reactions were carried out in a standard Schlenk line under N₂ atmosphere. Technical grade trioctylphosphine oxide (TOPO) (90%), technical grade trioctylphosphine (TOP) (90%), technical grade octylamine (OA) (90%), technical grade octadecene(ODE) (90%), CdO (99.5%), Zn acetate (99.99%), S powder (99.998%), and Se powder (99.99%) were obtained from Sigma Aldrich. N-octadecyl phosphonic acid (ODPA) was obtained from PCI Synthesis. ACS grade chloroform, and methanol were obtained from Fischer Scientific. Materials were used as received.

### Preparation of the One-Dimensional Nanoparticles—CdS Nanorods

First, 2.0 grams (g) (5.2 millimoles (mmol)) of TOPO, 0.67 g (2.0 mmol) of ODPA and 0.13 g (2.0 mmol) of CdO were prepared in a 50 ml three-neck round-bottom flask. The mixture was degassed at 150° C. for 30 minutes (min) under vacuum, and then heated to 350° C. under stirring. As Cd-ODPA complex was formed at 350° C., the brown solution in the flask became optically transparent and colorless after about 1 hour. Then, the solution was degassed at 150° C. for 10 minutes to remove by-products of complexation including O₂ and H₂O. After degassing, the solution was heated to 350° C. under a N₂ atmosphere. Sulfur (S) precursor containing 16 milligrams (mg) (0.5 mmol) of S dissolved in 1.5 milliliters (ml) of TOP was swiftly injected into the flask with a syringe. Consequently, the reaction mixture was quenched to 330° C. where the CdS growth was carried out. After 15 minutes, the CdS nanorods growth was terminated by cooling to 250° C. where the CdSe growth on CdS nanorods was carried out. An aliquot of the CdS nanorods was taken, and cleaned by precipitation with methanol and butanol for analysis. The CdS/CdSe heterostructures were formed by adding Se precursor to the same reaction flask, maintained under N₂ atmosphere as described below.

### Passivation of the Nanorods by the First Endcap—CdS/CdSe Nanorod Heterostructures

Following the formation of CdS nanorods, Se precursors containing 20 mg (0.25 mmol) of Se dissolved in 1.0 ml of TOP was slowly injected at 250° C. at a rate of 4 milliliters per hour (ml/h) via syringe pump (total injection time 15 minutes). Then, the reaction mixture was aged for an additional 5 minutes at 250° C. before the reaction flask was rapidly cooled by air jet. An aliquot of CdS/CdSe nanorod heterostructures was taken and cleaned by precipitation with methanol and butanol for analysis. The final solution was dissolved in chloroform and centrifuged at 2000 revolutions per minute (rpm). The precipitate was redissolved in chloroform and stored as a solution. The CdS band-edge absorption peak corresponds 0.75 when the solution is diluted by a factor of 10.

### Formation of the Second Endcap—CdS/CdSe/ZnSe Double Heterojunction Nanorods

CdS/CdSe/ZnSe double heterojunction nanorods were synthesized by growing ZnSe onto CdS/CdSe nanorod heterostructures. For Zn precursor, 6 ml of ODE, 2ml of OA and 0.18 g (1.0 mmol) of Zn acetate were degassed at 100° C. for 30 minutes. The mixture was heated to 250° C. under N₂ atmosphere and consequently Zn oleate was formed after 1 hour. 2 ml of previously prepared CdS/CdSe solution was injected into Zn oleate solution after cooling to 50° C. Chloroform in the mixture was allowed to evaporate for 30 min under vacuum. ZnSe growth was initiated by a slow injection of Se precursor containing 20 mg (0.25 mmol) of Se dissolved in 1.0 ml of TOP at 250° C. Thickness of ZnSe on CdS/CdSe nanorod heterostructures was controlled by the amount of Se injected. The ZnSe growth was terminated by removing heating mantle after injecting desired amount of Se precursor. Cleaning procedures were same as described for the CdS nanorods.

### Alternative Method for Forming the Second Endcap—CdS/CdSe/ZnSe double heterojunction Nanorods

Coordinating solvents such as TOA can alternatively be used for growing ZnSe. 5 ml of TOA, 1.2m1 of OA and 0.18 g (1.0 mmol) of Zn acetate were degassed at 100° C. for 30 minutes. The mixture was heated to 250° C. under N2 atmosphere and consequently Zn oleate was formed after 1 hour. 2 ml of previously prepared CdS/CdSe solution was injected into Zn oleate solution after cooling to 50° C. Chloroform in the mixture was allowed to evaporate for 30 min under vacuum. ZnSe growth was initiated by a slow injection of Se precursor containing 20 mg (0.25 mmol) of Se dissolved in 1.0 ml of TOP at 250° C. Thickness of ZnSe on CdS/CdSe nanorod heterostructures was controlled by the amount of Se injected. The ZnSe growth was terminated by removing heating mantle after injecting desired amount of Se precursor. Cleaning procedures were same as described for the CdS nanorods.

1. A method of producing a nanostructure material composite, comprising:
(a) providing on a first substrate a multiple-layer composite comprising 1) a nanostructure material layer and 2) one or more additional layers distinct from the nanostructure material layer;
(b) transferring the multiple-layer composite to a second substrate.

2. The method of claim 1 wherein the multiple-layer composite is contacted with a
stamp, and
the multiple-layer composite is deposited from the stamp on to the second substrate.

3. The method of claim 1, wherein the one or more additional functional layers comprise one or more of a charge transport layer, a charge injection layer, and/or an electrode layer.

4. The method of claim 1 wherein the multiple-layer composite further comprises an overcoating fluoro-containing layer.

5. A method of producing a nanostructure material composite, comprising:
(a) providing on a first substrate a layered composite comprising a nanostructure material layer with an overcoating fluoro-containing layer;
(b) contacting the layered composite with a stamp;
(c) depositing the layered composite from the stamp on a second substrate.

6. The method of claim 4, wherein the stamp contacts the fluoro-containing layer.

7. The method of claim 5, wherein the fluoro-containing layer comprises a fluorinated polymer.

8. The method of claim 5, further comprising removing the fluoro-containing layer after depositing the composite.

9. The method of claim 1 wherein a plurality of layered composites is deposited on the second substrate.

10. The method of claim 9 wherein at least one layered composite comprises a red emitting nanostructure material layer; and/or at least one layered composite comprises a green emitting nanostructure material layer; and/or at least one layered composite comprises a blue emitting nanostructure material layer.

11. The method of claim 1 wherein the second substrate comprises an anode layer.

12. The method of claims 9 wherein deposit of the layered composite provides a light-emitting device, a photodetector device, a chemical sensor, a photovoltaic device, a diode, a transistor or biologically active surface.

13. The method of claim 1, wherein the nanostructure material composite has dimensions of 200 μm by 200 μm or less.

14. The method of claim 1 wherein the nanostructure material comprises nanoparticles that comprise one or more heterojunctions.

15. The method of claim 1 wherein the nanostructure material comprises quantum dots.

16. A device comprising a composite comprising a nanostructure material layer with an overcoating fluoro-containing layer.
